(19) United States
(12) Patent Application Publication
(10) Pub. No.: US 2025/0180288 A1
(43) Pub. Date: Jun. 5, 2025

(54) SUBSTRATE PROCESSING APPARATUS, FLUID SUPPLY SYSTEM, AND SUBSTRATE PROCESSING METHOD

(71) Applicant: Tokyo Electron Limited, Tokyo (JP)

(72) Inventors: Takahiro HAYASHIDA, Kumamoto (JP); Mikio NAKASHIMA, Kumamoto (JP); Shigeru MORIYAMA, Kumamoto (JP)

(21) Appl. No.: 18/956,676

(22) Filed: Nov. 22, 2024

(30) Foreign Application Priority Data
Dec. 5, 2023 (JP) 2023-205034

(51) Int. Cl. F26B 5/00; G05D 23/19; H01L 21/02; H01L 21/67; H05B 1/02; H05B 3/00

(52) U.S. Cl. CPC F26B 5/005; G05D 23/1902; H01L 21/67248; H05B 1/0244; H01L 21/02101; H05B 3/0052

(57) ABSTRACT

A substrate processing apparatus includes a processing chamber configured to accommodate a substrate; a supply flow path configured to supply a processing fluid into the processing chamber; a heating mechanism configured to heat the processing fluid flowing through the supply flow path; a first temperature sensor configured to detect a temperature of the processing fluid downstream of the heating mechanism; a pressure sensor configured to detect a pressure of the processing fluid downstream of the heating mechanism; and a controller. The controller controls an output of the heating mechanism based on the pressure of the processing fluid detected by the pressure sensor and the temperature of the processing fluid detected by the first temperature sensor.

### CROSS-REFERENCE TO RELATED APPLICATIONS

This patent application is based on and claims priority to Japanese Patent Application No. 2023-205034 filed on Dec. 5, 2023, the entire contents of which are incorporated herein by reference.

### TECHNICAL FIELD

The present disclosure relates to a substrate processing apparatus, a fluid supply system, and a substrate processing method.

### BACKGROUND

A technique of drying a substrate by using a supercritical fluid is known. Patent Document 1 discloses a configuration in which a heater and two temperature sensors are provided in a supply line for supplying a supercritical fluid into a chamber, and the temperature sensors used to control the heater are switched between a period in which the supercritical fluid flows in the supply line and a period in which the supercritical fluid does not flow in the supply line.

### RELATED ART DOCUMENT

### Patent Document

[Patent Document 1] Japanese Laid-open Patent Application Publication No. 2021-086857

### SUMMARY

A substrate processing apparatus according to an aspect of the present disclosure includes a processing chamber configured to accommodate a substrate; a supply flow path configured to supply a processing fluid into the processing chamber; a heating mechanism configured to heat the processing fluid flowing through the supply flow path; a first temperature sensor configured to detect a temperature of the processing fluid downstream of the heating mechanism; a pressure sensor configured to detect a pressure of the processing fluid downstream of the heating mechanism; and a controller. The controller controls an output of the heating mechanism based on the pressure of the processing fluid detected by the pressure sensor and the temperature of the processing fluid detected by the first temperature sensor.

### BRIEF DESCRIPTION OF THE DRAWINGS

FIG. 1 is a diagram illustrating a substrate processing apparatus according to an embodiment;

FIG. 2 is a diagram illustrating an example of a positional relationship between a heating mechanism and a temperature sensor;

FIG. 3 is a flowchart illustrating a substrate processing method according to the embodiment;

FIG. 4 is a graph indicating a pressure change in a processing chamber in the substrate processing method of FIG. 3;

FIG. 5 is a chart indicating an example of a hypothetical temperature;

FIG. 6 is a diagram (1) illustrating the substrate processing method according to the embodiment;

FIG. 7 is a diagram (2) illustrating the substrate processing method according to the embodiment;

FIG. 8 is a diagram (3) illustrating the substrate processing method according to the embodiment;

FIG. 9 is a diagram (4) illustrating the substrate processing method according to the embodiment;

FIG. 10 is a diagram (5) illustrating the substrate processing method according to the embodiment;

FIG. 11 is a diagram (6) illustrating the substrate processing method according to the embodiment;

FIG. 12 is a diagram (7) illustrating the substrate processing method according to the embodiment;

FIG. 13 is a diagram (8) illustrating the substrate processing method according to the embodiment;

FIG. 14 is a diagram (9) illustrating the substrate processing method according to the embodiment;

FIG. 15 is a graph indicating a temperature change in a case where the heating mechanism is controlled based on only a temperature detected by a first temperature sensor;

FIG. 16 is a graph indicating a temperature change in a case where the heating mechanism is controlled based on only a temperature detected by a second temperature sensor;

FIG. 17 is a graph indicating a temperature change in a case where the heating mechanism is controlled based on the hypothetical temperature;

FIG. 18 is a diagram illustrating a heating mechanism according to a first modified example; and

FIG. 19 is a diagram illustrating a heating mechanism according to a second modified example.

### DETAILED DESCRIPTION

Non-restrictive exemplary embodiments of the present disclosure will be described below with reference to the accompanying drawings. In all the accompanying drawings, the same or corresponding members or parts are denoted by the same or corresponding reference symbols, and duplicated description will be omitted.

### [Substrate Processing Apparatus]

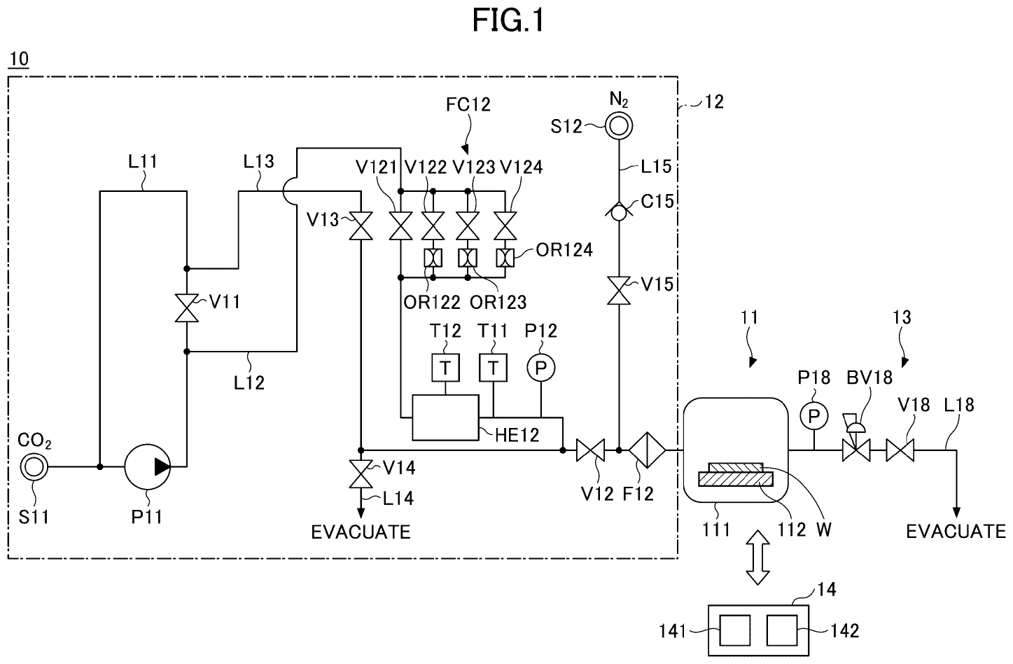

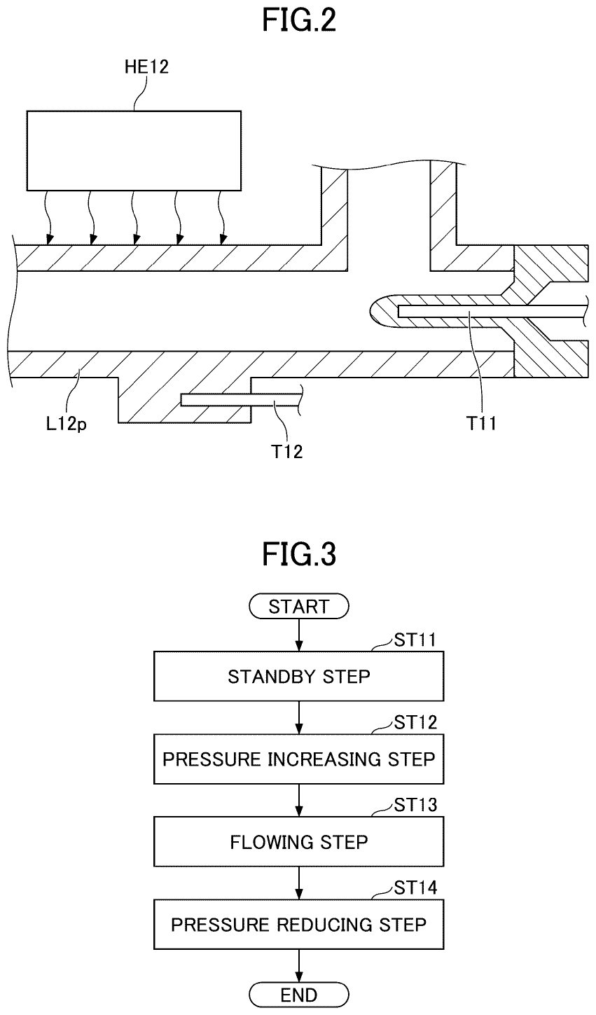

A substrate processing apparatus 10 according to the embodiment will be described with reference to FIG. 1 and FIG. 2. FIG. 1 is a diagram illustrating the substrate processing apparatus 10 according to the embodiment. FIG. 2 is a diagram illustrating an example of a positional relationship between a heating mechanism HE12 and temperature sensors (a first temperature sensor T11 and a second temperature sensor T12).

The substrate processing apparatus 10 includes a processing section 11, a fluid supply system 12, an evacuation section 13, and a controller 14.

The processing section 11 includes a processing chamber 111 and a holder 112. The processing chamber 111 is a chamber in which a processing space configured to accommodate a substrate W having, for example, a 300 mm diameter is formed. In the processing space, a substrate on which a liquid film is formed is processed, for example. The substrate W may be, for example, a semiconductor wafer. The holder 112 is provided inside the processing chamber 111. The holder 112 holds the substrate W horizontally. The holder 112 is configured integrally with the processing chamber 111, for example. The holder 112 may be a holding plate configured separately from the processing chamber 111. The processing section 11 may include a temperature sensor and a pressure sensor.

The fluid supply system 12 includes a processing fluid supply source S11, an inert gas supply source S12, a circulation flow path L11, a first supply flow path L12, a return flow path L13, a pressure relief flow path L14, and a second supply flow path L15.

The processing fluid supply source S11 is a supply source of a processing fluid. The processing fluid may be, for example, carbon dioxide gas (CO₂) in a gas or liquid state.

The inert gas supply source S12 is a supply source of an inert gas. The inert gas may be, for example, nitrogen gas (N₂).

The circulation flow path L11 is connected to the processing fluid supply source S11. The circulation flow path L11 circulates the processing fluid. A pump P11 and an on-off valve V11 are provided in the circulation flow path L11. The pump P11 delivers the processing fluid to the downstream side of the circulation flow path L11. The on-off valve V11 is a valve for switching the flow of the processing fluid between on and off. The on-off valve V11 circulates the processing fluid in the circulation flow path L11 while in an open state, and does not circulate the processing fluid in the circulation flow path L11 while in a closed state. An on-off valve, an orifice, a temperature sensor, and a pressure sensor may be further provided in the circulation flow path L11 at various positions.

The first supply flow path L12 connects the circulation flow path L11 to the processing chamber 111 at a point downstream of the pump P11 and upstream of the on-off valve V11. The first supply flow path L12 supplies the processing fluid from the circulation flow path L11 into the processing chamber 111. The first supply flow path L12 includes a pipe L12p (FIG. 2) through which the processing fluid flows. In the first supply flow path L12, a flow rate adjustment mechanism FC12, the heating mechanism HE12, the second temperature sensor T12, the first temperature sensor T11, a pressure sensor P12, an on-off valve V12, and a filter F12 are provided in this order from the upstream side.

The flow rate adjustment mechanism FC12 is provided upstream of the heating mechanism HE12. The flow rate adjustment mechanism FC12 includes on-off valves V121, V122, V123, and V124, and orifices OR122, OR123, and OR124.

The on-off valves V121, V122, V123, and V124 are connected in parallel with each other. The on-off valves V121, V122, V123, and V124 are valves for switching the flow of the processing fluid between on and off. The on-off valves V121, V122, V123, and V124 allow the processing fluid to flow to the heating mechanism HE12 downstream while in an open state, and do not allow the processing fluid to flow to the heating mechanism HE12 on the downstream side while in a closed state.

The orifice OR122 is connected in series with the on-off valve V122. The orifice OR123 is connected in series with the on-off valve V123. The orifice OR124 is connected in series with the on-off valve V124. The orifices OR122, OR123, and OR124 serve to reduce the flow rate of the processing fluid flowing through the first supply flow path L12 to regulate the pressure of the processing fluid. The orifices OR122, OR123, and OR124 allow the pressure-regulated processing fluid to flow to the heating mechanism HE12 downstream. Here, an orifice may be connected in series with the on-off valve V121 on the downstream side of the on-off valve V121.

The heating mechanism HE12 heats the processing fluid to a set temperature and supplies the processing fluid heated at the set temperature to the downstream side. The set temperature may be variable. The set temperature includes, for example, a first temperature and a second temperature. The first temperature is 15° C. or greater and 100° C. or less, and is, for example, 80° C. The second temperature is greater than the first temperature. The second temperature is 150° C. or less, and is, for example, 120° C.

The heating mechanism HE12 is provided outside the pipe L12p. The heating mechanism HE12 heats the pipe L12p and the processing fluid flowing through the pipe L12p from the outside of the pipe L12p. The heating mechanism HE12 heats the pipe L12p and the processing fluid flowing through the pipe L12p by radiating light toward the pipe L12p, for example. When optical heating is used, the thermal capacity is small, and therefore, the temperature responsiveness is high. The heating mechanism HE12 is, for example, a lamp heater using a halogen lamp, a xenon lamp, or the like. The heating mechanism HE12 may be a heater using a laser, a light emitting diode (LED), or the like.

The first temperature sensor T11 detects the temperature of the processing fluid downstream of the heating mechanism HE12. The first temperature sensor T11 includes a temperature measurement element inserted into the pipe L12p downstream of the heating mechanism HE12 and detects the temperature of the processing fluid flowing through the pipe L12p.

The second temperature sensor T12 detects the temperature of the processing fluid at the position where the heating mechanism HE12 is provided. The second temperature sensor T12 is provided such that a temperature measurement element is in contact with an outer wall of the pipe L12p at the position where the heating mechanism HE12 is provided, and detects the temperature of the pipe L12p.

The pressure sensor P12 is provided in the first supply flow path L12 between the heating mechanism HE12 and the on-off valve V12. The pressure sensor P12 detects the pressure of the processing fluid flowing the first supply flow path L12 between the heating mechanism HE12 and the on-off valve V12. The pressure sensor P12 may be provided in the first supply flow path L12 between the on-off valve V12 and the filter F12, or may be provided in the first supply flow path L12 between the filter F12 and the processing chamber 111.

The on-off valve V12 is a valve for switching the flow of the processing fluid between on and off. The on-off valve V12 allows the processing fluid to flow to the filter F12 downstream while in an open state, and does not allow the processing fluid to flow to the filter F12 downstream while in a closed state.

The filter F12 filters the processing fluid flowing through the first supply flow path L12 to remove foreign substances contained in the processing fluid. This can suppress the generation of particles on the surface of the substrate W during the substrate processing using the processing fluid.

A line heater may be provided downstream of the heating mechanism HE12 in the first supply flow path L12. The line heater heats a portion of the first supply flow path L12 that is located downstream of the heating mechanism HE12. The line heater suppresses a temperature decrease of the processing fluid, which has been heated to a set temperature by the heating mechanism HE12, when the processing fluid flows through the first supply flow path L12. An on-off valve, an orifice, a temperature sensor, and a pressure sensor may be provided in the first supply flow path L12 at various positions.

The return flow path L13 connects the first supply flow path L12, at a point downstream of the heating mechanism HE12 and upstream of the on-off valve V12, to the circulation flow path L11, at a point downstream of the on-off valve V11. The return flow path L13 returns the processing fluid from the first supply flow path L12 to the circulation flow path L11. An on-off valve V13 is provided in the return flow path L13.

The on-off valve V13 is a valve for switching the flow of the processing fluid between on and off. The on-off valve V13 allows the processing fluid to flow through the circulation flow path L11 located downstream while in an open state, and does not allow the processing fluid to flow through the circulation flow path L11 located downstream while in a closed state.

The pressure relief flow path L14 branches from the return flow path L13 downstream of a branching point of the return flow path L13 from the first supply flow path L12 and upstream of the on-off valve V13. The pressure relief flow path L14 evacuates the processing fluid in the return flow path L13. An on-off valve V14 is provided in the pressure relief flow path L14.

The on-off valve V14 allows the processing fluid to flow through the pressure relief flow path L14 downstream of the on-off valve V14 while in an open state, and does not allow the processing fluid to flow through the pressure relief flow path L14 downstream of the on-off valve V14 while in a closed state.

The second supply flow path L15 is connected upstream to the inert gas supply source S12 and connected downstream to a point on the first supply flow path L12 between the on-off valve V12 and the filter F12. The second supply flow path L15 supplies the inert gas to the first supply flow path L12 between the on-off valve V12 and the filter F12. A check valve C15 and an on-off valve V15 are provided in this order from the upstream side in the second supply flow path L15.

The check valve C15 prevents the processing fluid from flowing back from the first supply flow path L12 to the inert gas supply source S12.

The on-off valve V15 is a valve for switching the flow of the inert gas between on and off. The on-off valve V15 allows the inert gas to flow through the first supply flow path L12 located downstream while in an open state, and does not allow the inert gas to flow through the first supply flow path L12 located downstream while in a closed state.

A heating mechanism, a line heater, an on-off valve, an orifice, a temperature sensor, and a pressure sensor may be further provided at various positions in the second supply flow path L15.

The evacuation section 13 includes an evacuation flow path L18. The evacuation flow path L18 is connected to the processing chamber 111. A pressure sensor P18, a back pressure valve BV18, and an on-off valve V18 are provided in this order from the upstream side in the evacuation flow path L18.

The pressure sensor P18 detects the pressure of the fluid flowing through the evacuation flow path L18 immediately after the processing chamber 111. With this, the pressure in the processing chamber 111 can be detected.

When the pressure on the primary side of the evacuation flow path L18 exceeds a set pressure, the back pressure valve BV18 adjusts the valve opening degree to allow the fluid to flow to the secondary side, thereby maintaining the pressure on the primary side at the set pressure. For example, the set pressure of the back pressure valve BV18 is adjusted by the controller 14.

The on-off valve V18 is a valve for switching the flow of the fluid between on and off. The on-off valve V18 allows the fluid to flow through the evacuation flow path L18 downstream of the on-off valve V18 while in an open state, and does not allow the fluid to flow through the evacuation flow path L18 downstream of the on-off valve V18 while in a closed state.

A line heater may be provided in the evacuation flow path L18. The line heater heats the evacuation flow path L18. An on-off valve, an orifice, a temperature sensor, and a pressure sensor may be further provided at various positions in the evacuation flow path L18.

The controller 14 is, for example, a computer, and includes an arithmetic unit 141 and a storage unit 142. The storage unit 142 stores programs for controlling various processes performed in the substrate processing apparatus 10. The arithmetic unit 141 controls the operation of the substrate processing apparatus 10 by reading and executing the program stored in the storage unit 142. The program may be recorded in a computer-readable storage medium and installed from the storage medium into the storage unit 142 of the controller 14. Examples of the computer-readable storage medium include a hard disk (HD), a flexible disk (FD), a compact disc (CD), a magneto-optical disk (MO), a memory card, and the like. The controller 14 may be included in the fluid supply system 12.

The controller 14 receives measurement signals from various sensors (the first temperature sensor T11, the second temperature sensor T12, the pressure sensor P18, and the like), and transmits control signals to various functional elements. Examples of the control signals include opening/closing signals of the on-off valves V11, V12, V121, V122, V123, V124, V13, V14, V15, and V18, a set pressure signal of the back pressure valve BV18, a set temperature signal of the heating mechanism HE12, and a set temperature signal of the line heater.

The controller 14 may control the output of the heating mechanism HE12 based on the pressure of the processing fluid detected by the pressure sensor P12, the temperature of the processing fluid detected by the first temperature sensor T11, and the temperature of the pipe L12p detected by the second temperature sensor T12.

The controller 14 calculates a hypothetical temperature T by, for example, a calculation equation of Equation (1), and controls the output of the heating mechanism HE12 based on the calculated hypothetical temperature T.

$$T = α {T}_{1} + β {T}_{2} \qquad ( 1 )$$

In Equation (1), T is the hypothetical temperature, T₁ is the temperature of the processing fluid detected by the first temperature sensor T11, and T₂ is the temperature of the pipe L12p detected by the second temperature sensor T12. α is a first weight coefficient associated with the pressure of the processing fluid detected by the pressure sensor P12. B is a second weight coefficient associated with the pressure of the processing fluid detected by the pressure sensor P12. A value obtained by adding α and β is always 1 (α+β=1). αT₁ is a first calculation temperature obtained by multiplying the temperature T₁ detected by the first temperature sensor T11 by the first weight coefficient α. βT₂ is a second calculation temperature obtained by multiplying the temperature T₂ detected by the second temperature sensor T12 by the second weight coefficient β.

For example, when the first weight coefficient α is set to be relatively large (the second weight coefficient β is set to be relatively small), the first calculation temperature αT₁ becomes relatively large, and the contribution of the temperature of the processing fluid detected by the first temperature sensor T11 increases. For example, when the first weight coefficient α is set to be relatively small (the second weight coefficient β is set to be relatively large), the second calculation temperature βT₂ becomes relatively large, and the contribution of the temperature of the pipe L12p detected by the second temperature sensor T12 increases.

When the pressure of the processing fluid detected by the pressure sensor P12 is a first pressure, the controller 14 may set the first weight coefficient α to a value less than the first weight coefficient α that is set when the pressure of the processing fluid detected by the pressure sensor P12 is a second pressure that is higher than the first pressure. Because the response speed of the first temperature sensor T11 is low when the pressure detected by the pressure sensor P12 is small, by setting the first weight coefficient α to be relatively small (set the second weight coefficient β to be relatively large) to increase the contribution of the second temperature sensor T12, the temperature controllability is improved.

When the processing fluid does not flow through the pipe L12p, the controller 14 may set the second weight coefficient β to a value greater than the first weight coefficient α (α<β). When the processing fluid does not flow through the pipe L12p, the response speed of the first temperature sensor T11 is very low. Therefore, by reducing the contribution of the first temperature sensor T11 and increasing the contribution of the second temperature sensor T12, the temperature controllability is improved.

When the processing fluid in a gas state flows through the pipe L12p, the controller 14 may set the second weight coefficient β to a value greater than the first weight coefficient α (α<β) and set the first weight coefficient α to a value greater than the first weight coefficient α that is set when the processing fluid does not flow through the pipe L12p. When the processing fluid in the gas state flows through the pipe L12p, the response speed of the first temperature sensor T11 is low. Thus, by reducing the contribution of the first temperature sensor T11 and increasing the contribution of the second temperature sensor T12, the temperature controllability is improved. However, when the processing fluid in the gas state flows through the pipe L12p, the response speed of the first temperature sensor T11 is higher than that when the processing fluid does not flow in the pipe L12p. Therefore, when the processing fluid in the gas state flows through the pipe L12p, the first weight coefficient α may be set to a value greater than the first weight coefficient α that is set when the processing fluid does not flow through the pipe L12p.

When the processing fluid in the supercritical state flows through the pipe L12p, the controller 14 may set the first weight coefficient α to a value greater than the second weight coefficient β (α>β). When the processing fluid in the supercritical state flows through the pipe L12p, the response speed of the first temperature sensor T11 is high. Therefore, by increasing the contribution of the first temperature sensor T11 and reducing the contribution of the second temperature sensor T12, the temperature controllability is improved.

For example, the controller 14 may control the output of the heating mechanism HE12 while supplying the processing fluid into the processing chamber 111. In the case of the heating mechanism HE12 using optical heating, the thermal capacity is small, and thus, the temperature responsiveness is high. Therefore, the temperature of the processing fluid can be changed in a short time.

For example, the controller 14 may circulate the processing fluid through the circulation flow path L11, the first supply flow path L12, and the return flow path L13, while the processing fluid in the processing chamber 111 is evacuated from the evacuation flow path L18 without the processing fluid being supplied into the processing chamber 111. In this case, the evacuation of the processing fluid from the processing chamber 111 and the preparation of the processing fluid to be used for the processing on the next substrate W can be performed in parallel. Therefore, the processing time in continuous processing can be shortened.

For example, the controller 14 may circulate the processing fluid through the circulation flow path L11, the first supply flow path L12, and the return flow path L13 until the hypothetical temperature reaches the set temperature. In this case, the processing fluid at the set temperature is supplied into the processing chamber 111 immediately after the on-off valve V12 is opened. Therefore, the temperature can be suppressed from fluctuating immediately after the processing fluid is supplied.

For example, the controller 14 may control the on-off valves V14 to evacuate the processing fluid in the return flow path L13 from the pressure relief flow path L14 before the processing fluid is supplied into the processing chamber 111. In this case, the high-pressure processing fluid is prevented from being supplied into the processing chamber 111 immediately after the on-off valve V12 is opened. This can prevent the processing fluid from being supplied to the substrate W at a high speed, and thus pattern collapse can be suppressed.

For example, the controller 14 may increase the pressure in the processing chamber 111 by setting the supply flow rate of the processing fluid to be supplied into the processing chamber 111 to a first flow rate until the pressure in the processing chamber 111 reaches the first pressure. Additionally, when the pressure in the processing chamber 111 reaches the first pressure, the controller 14 may further increase the pressure in the processing chamber 111 by setting the supply flow rate to a second flow rate that is greater than the first flow rate. In this case, the supply of the processing fluid to the substrate W at a high speed in the initial stage is prevented, and pattern collapse can be suppressed.

In the substrate processing apparatus 10 according to the embodiment, the controller 14 controls the output of the heating mechanism HE12 based on the pressure of the processing fluid detected by the pressure sensor P12, the temperature of the processing fluid detected by the first temperature sensor T11, and the temperature of the pipe L12p detected by the second temperature sensor T12. In this case, the hypothetical temperature is calculated based on the temperature of the processing fluid detected by the first temperature sensor T11 and the temperature of the pipe L12p detected by the second temperature sensor T12 according to the state of the processing fluid, and the output of the heating mechanism HE12 can be controlled based on the calculated hypothetical temperature. Therefore, the temperature of the processing fluid can be brought close to the set temperature regardless of the state of the processing fluid.

### [Substrate Processing Method]

A substrate processing method performed by using the substrate processing apparatus 10 will be described with reference to FIG. 3 to FIG. 14. The substrate processing method described below is automatically performed under the control of the controller 14 based on the processing recipe and the control program stored in the storage unit 142.

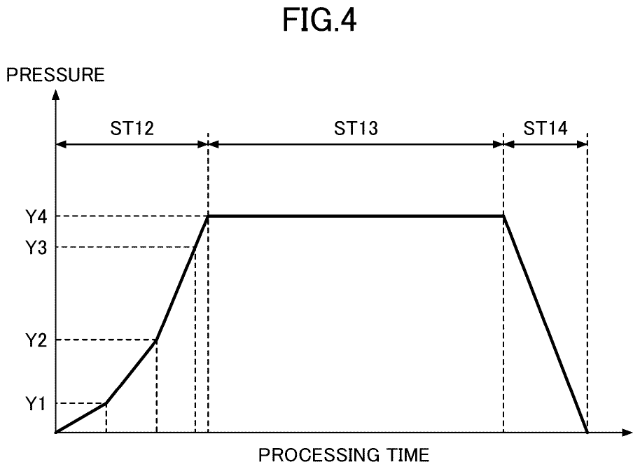

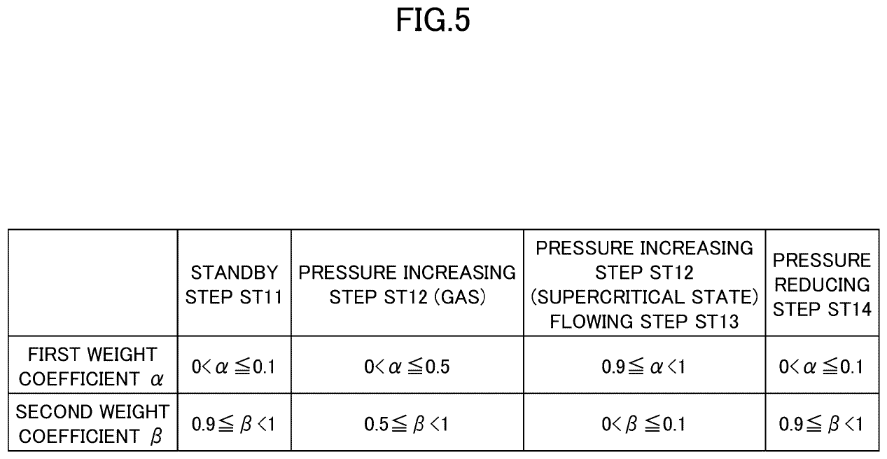

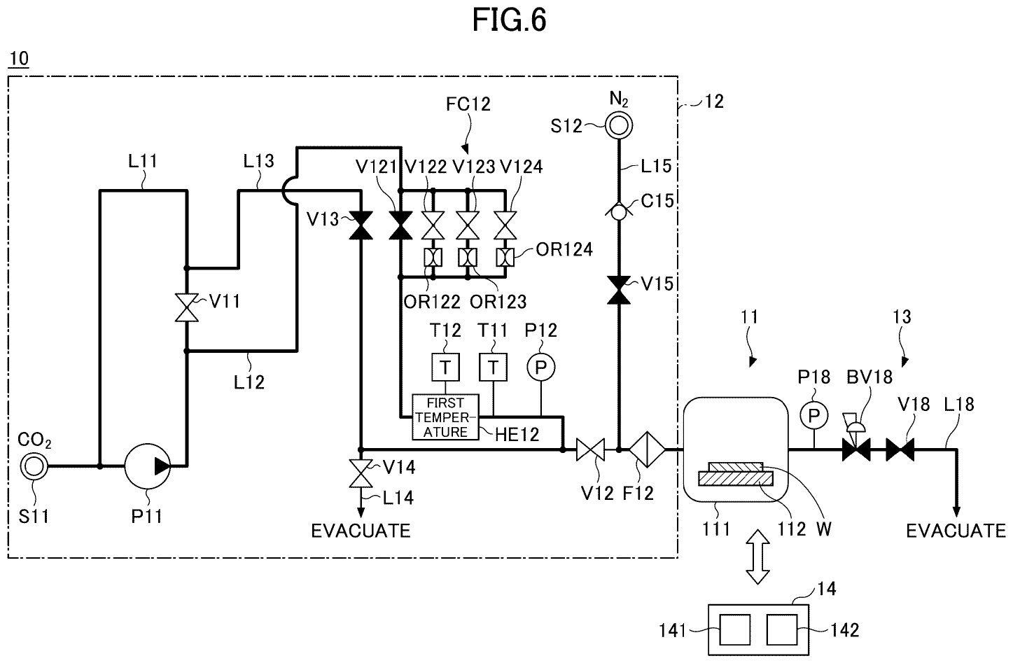

FIG. 3 is a flowchart illustrating the substrate processing method according to the embodiment. FIG. 4 is a graph indicating a pressure change in the processing chamber 111 in the substrate processing method of FIG. 3. FIG. 5 is a chart indicating an example of the hypothetical temperature. FIG. 6 to FIG. 14 are diagrams illustrating the substrate processing method according to the embodiment. In FIG. 6 to FIG. 14, the on-off valves in the open state are illustrated in black, and the on-off valves in the closed state are illustrated in white. In FIG. 6 to FIG. 14, the flow path through which the fluid flows is indicated by a thick solid line.

As illustrated in FIG. 3, the substrate processing method according to the embodiment includes a standby step ST11, a pressure increasing step ST12, a flowing step ST13, and a pressure reducing step ST14. The following description assumes that the substrate W is carried into the processing chamber 111 in advance before the standby step ST11. The substrate W is placed on the holder 112 in a state where the substrate W has undergone a cleaning process and a recess of the pattern on the surface is filled with isopropyl alcohol (IPA).

### <Standby Step ST11>

First, as illustrated in FIG. 6, the set temperature of the heating mechanism HE12 is set to the first temperature, for example, 80° C., the on-off valves V121, V13, V15, and V18 are opened, and the on-off valves V11, V12, V122, V123, V124, and V14 are closed. With this, the processing fluid of the processing fluid supply source S11 circulates through the circulation flow path L11, the first supply flow path L12, the return flow path L13, and the circulation flow path L11 in this order. The processing fluid is heated to the first temperature by the heating mechanism HE12 in the first supply flow path L12. The processing fluid circulates through the circulation flow path L11, the first supply flow path L12, the return flow path L13, and the circulation flow path L11 in this order, so that the temperature of each flow path approaches the first temperature. In the standby step ST11, the processing fluid may circulate through the circulation flow path L11, the first supply flow path L12, and the return flow path L13 until the hypothetical temperature reaches the first temperature. In this case, the processing fluid at the first temperature is supplied into the processing chamber 111 immediately after the on-off valve V12 is opened. Therefore, temperature fluctuations caused immediately after the processing fluid is supplied can be reduced. Additionally, the inert gas of the inert gas supply source S12 is supplied into the processing chamber 111 through the second supply flow path L15 and the first supply flow path L12, and is evacuated through the evacuation flow path L18.

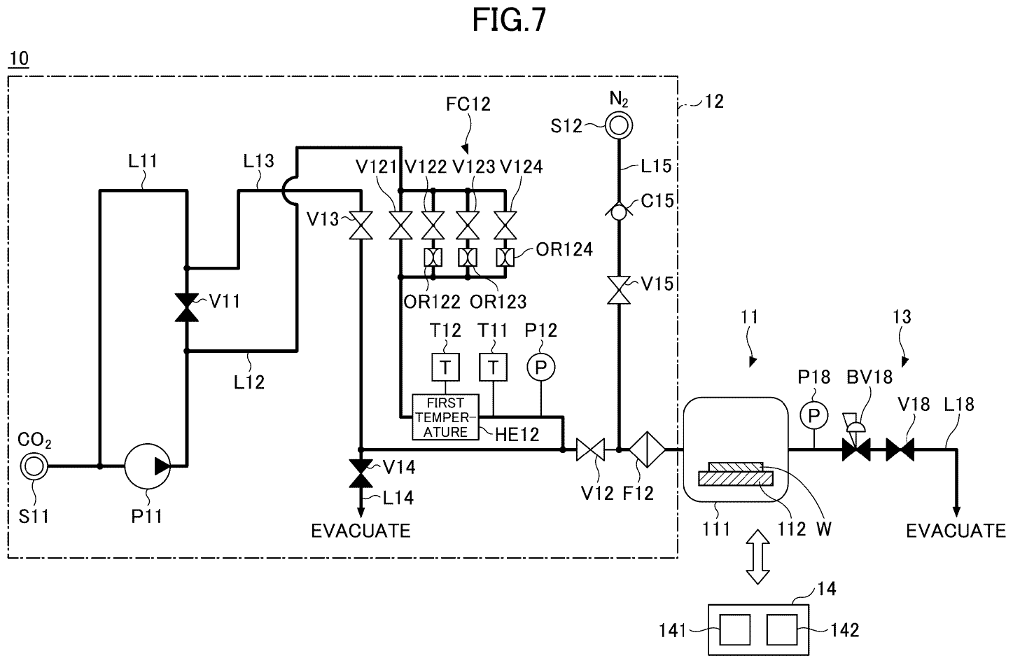

Next, as illustrated in FIG. 7, the on-off valves V13 and V121 switch from open to closed, and the on-off valves V11 and V14 switch from closed to open. With this, the circulation of the processing fluid in the circulation flow path L11, the first supply flow path L12, and the return flow path L13 is stopped. Additionally, the processing fluid in the first supply flow path L12 between the flow rate adjustment mechanism FC12 and the on-off valve V12 and the processing fluid in the return flow path L13 between the on-off valve V12 and the on-off valve V13 are evacuated from the pressure relief flow path L14. Thus, the pressure in the first supply flow path L12 between the flow rate adjustment mechanism FC12 and the on-off valve V12 and the pressure in the return flow path L13 between the on-off valve V12 and the on-off valve V13 are reduced. In this case, the high-pressure processing fluid is prevented from being supplied into the processing chamber 111 immediately after the on-off valve V12 is opened. This prevents the processing fluid from being supplied to the substrate W at a high speed, and thus pattern collapse can be suppressed. Additionally, the on-off valve V15 switches from open to closed. With this, the inert gas in the processing chamber 111 is evacuated from the evacuation flow path L18.

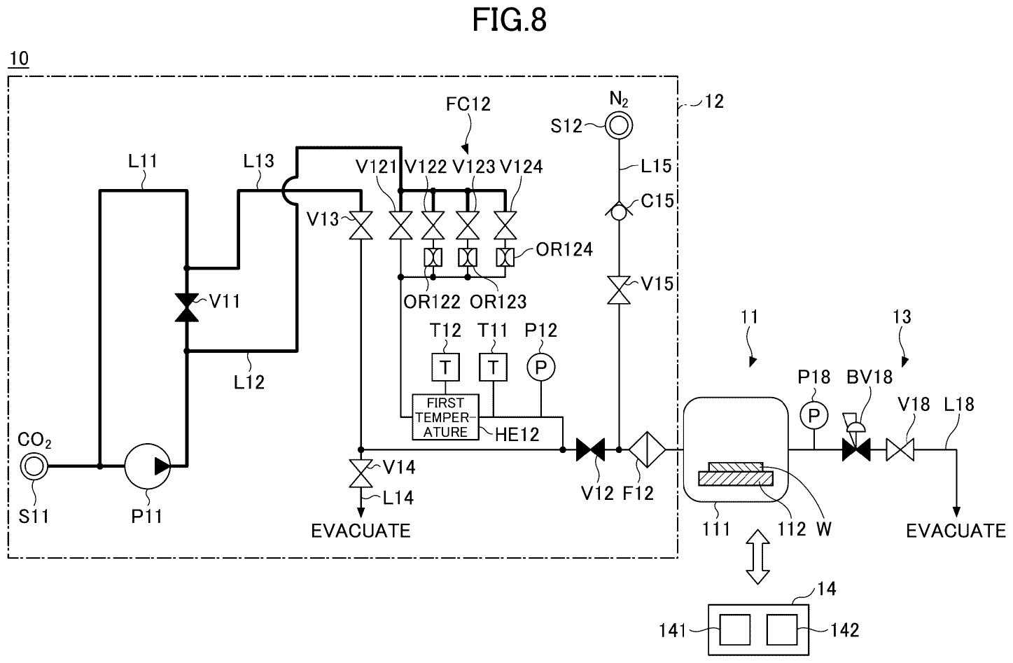

Next, as illustrated in FIG. 8, the on-off valve V18 switches from open to closed, and the on-off valve V12 switches from closed to open.

During this series of operations, the controller 14 receives the outputs from the pressure sensor P12, the first temperature sensor T11, and the second temperature sensor T12, calculates the hypothetical temperature by Equation (1), and controls the output of the heating mechanism HE12 based on the calculated hypothetical temperature.

In the standby step ST11, the processing fluid does not flow through the pipe L12p, or the processing fluid in the gas state flows through the pipe L12p. Thus, the controller 14 sets the second weight coefficient β to a value greater than the first weight coefficient α. As illustrated in FIG. 5, the controller 14 sets the first weight coefficient α in the range of 0<α≤0.1, and sets the second weight coefficient β in the range of 0.9≤β<1, for example. When the processing fluid does not flow in the pipe L12p or when the pipe L12p is filled with the processing fluid in the gas state, the response speed of the first temperature sensor T11 is low. Therefore, by reducing the contribution of the first temperature sensor T11 and increasing the contribution of the second temperature sensor T12, the temperature controllability is improved. The controller 14 determines which state, among multiple states, is the current state in the pipe L12p, based on the pressure of the processing fluid detected by the pressure sensor P12, for example. The multiple states may include a state in which the processing fluid does not flow in the pipe L12p, a state in which the processing fluid in the gas state flows in the pipe L12p, and a state in which the processing fluid in the supercritical state flows in the pipe L12p.

### <Pressure Increasing Step ST12>

The pressure increasing step ST12 is performed after the standby step ST11. In the pressure increasing step ST12, first, the pressure in the processing chamber 111 is increased by supplying the processing fluid at the first flow rate and at the first temperature (a first pressure increasing step). Next, the pressure in the processing chamber 111 is increased by supplying the processing fluid at the second flow rate and at the first temperature (a second pressure increasing step). Next, the pressure in the processing chamber 111 is increased by supplying the processing fluid at a third flow rate and at the first temperature (a third pressure increasing step). Next, the pressure in the processing chamber 111 is increased by supplying the processing fluid at the third flow rate and at the second temperature, for example, 120° C. (a fourth pressure increasing step). The magnitude relationship among the first flow rate, the second flow rate, and the third flow rate is the first flow rate<the second flow rate<the third flow rate. The second temperature is greater than the first temperature.

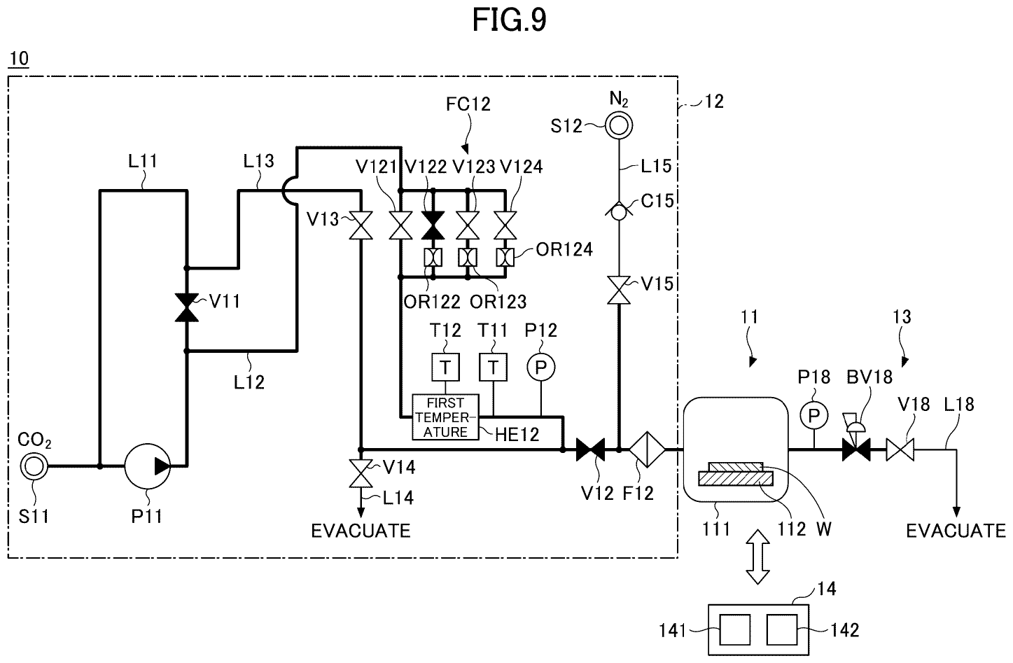

In the first pressure increasing step, as illustrated in FIG. 9, the on-off valve V122 switches from closed to open. With this, the processing fluid of the processing fluid supply source S11 is supplied into the processing chamber 111 through the circulation flow path L11 and the first supply flow path L12. At this time, the processing fluid is adjusted to the first flow rate by passing through the orifice OR122, and is adjusted to the first temperature by passing through the heating mechanism HE12. Therefore, the processing fluid at the first flow rate and at the first temperature is supplied into the processing chamber 111. In the first pressure increasing step, the on-off valve V18 is closed, and thus the processing fluid does not flow out from the processing chamber 111. Therefore, the pressure in the processing chamber 111 gradually increases. As a result, pattern collapse can be suppressed.

During the first pressure increasing step, the pressure in the processing chamber 111 is detected by the pressure sensor P18, and the increasing of the pressure at the first flow rate is continued until the pressure in the processing chamber 111 reaches a first pressure Y1 (see FIG. 4). When the pressure in the processing chamber 111 reaches the first pressure Y1, the first pressure increasing step is terminated and the process transitions to a second pressure increasing step.

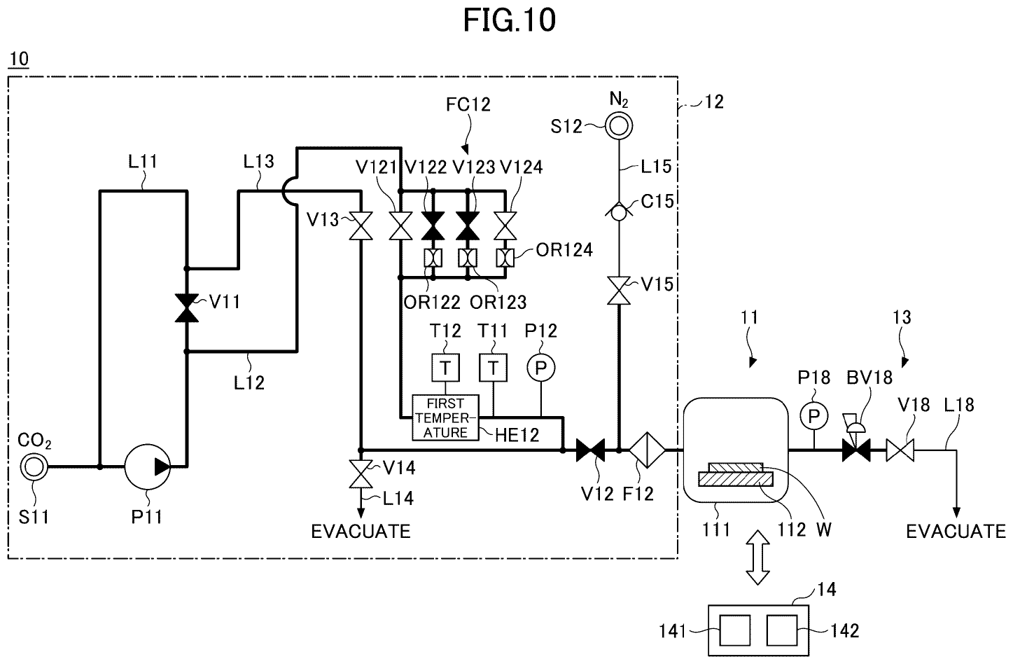

In the second pressure increasing step, as illustrated in FIG. 10, the on-off valve V123 switches from closed to open. With this, the processing fluid of the processing fluid supply source S11 is adjusted to the second flow rate by passing through the orifices OR122 and OR123, and is adjusted to the first temperature by passing through the heating mechanism HE12. Therefore, the processing fluid at the second flow rate and at the first temperature is supplied into the processing chamber 111. In the second pressure increasing step, the on-off valve V18 is closed, and thus the processing fluid does not flow out from the processing chamber 111. Therefore, the pressure in the processing chamber 111 gradually increases. In the second pressure increasing step, the pressure is increased by the processing fluid at a flow rate larger than that in the first pressure increasing step, thereby increasing the speed of the pressure increase.

During the second pressure increasing step, the pressure in the processing chamber 111 is detected by the pressure sensor P18, and the increase of the pressure at the second flow rate is continued until the pressure in the processing chamber 111 reaches a second pressure Y2 (see FIG. 4). When the pressure in the processing chamber 111 reaches the second pressure Y2, the second pressure increasing step is terminated and the process transitions to the third pressure increasing step.

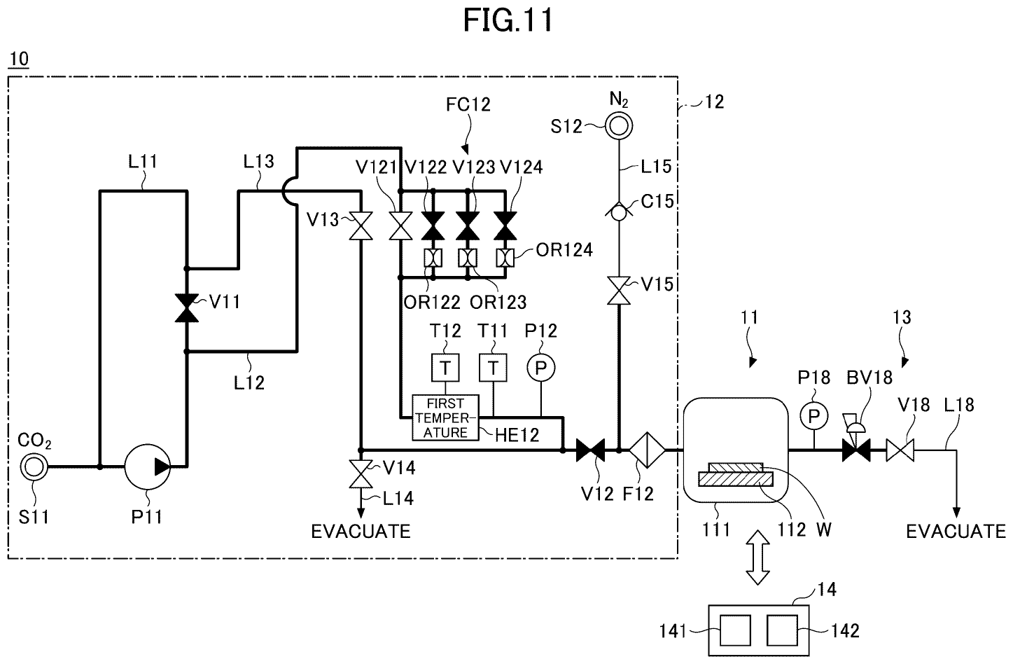

In the third pressure increasing step, as illustrated in FIG. 11, the on-off valve V124 switches from closed to open. With this, the processing fluid of the processing fluid supply source S11 is adjusted to the third flow rate by passing through the orifices OR122, OR123, and OR124, and is adjusted to the first temperature by passing through the heating mechanism HE12. Therefore, the processing fluid at the third flow rate and at the first temperature is supplied into the processing chamber 111. In the third pressure increasing step, the on-off valve V18 is closed, and thus the processing fluid does not flow out from the processing chamber 111. Therefore, the pressure in the processing chamber 111 gradually increases. In the third pressure increasing step, the pressure is increased by the processing fluid at a flow rate that is greater than that in the second pressure increasing step, thereby further increasing the speed of the pressure increase.

In the pressure increase at the third flow rate, the pressure of the processing fluid supplied into the processing chamber 111 is lower than the critical pressure. Thus, the processing fluid is supplied into the processing chamber 111 in the gas state. Subsequently, the pressure in the processing chamber 111 increases as the filling of the processing fluid into the processing chamber 111 progresses. When the pressure in the processing chamber 111 exceeds the critical pressure, the processing fluid present in the processing chamber 111 is in the supercritical state.

During the third pressure increasing process, the pressure in the processing chamber 111 is detected by the pressure sensor P18, and the pressure increase at the third flow rate is continued until the pressure in the processing chamber 111 reaches a third pressure Y3 (see FIG. 4). When the pressure in the processing chamber 111 reaches the third pressure Y3, the third pressure increasing step is terminated and the process transitions to the fourth pressure increasing step.

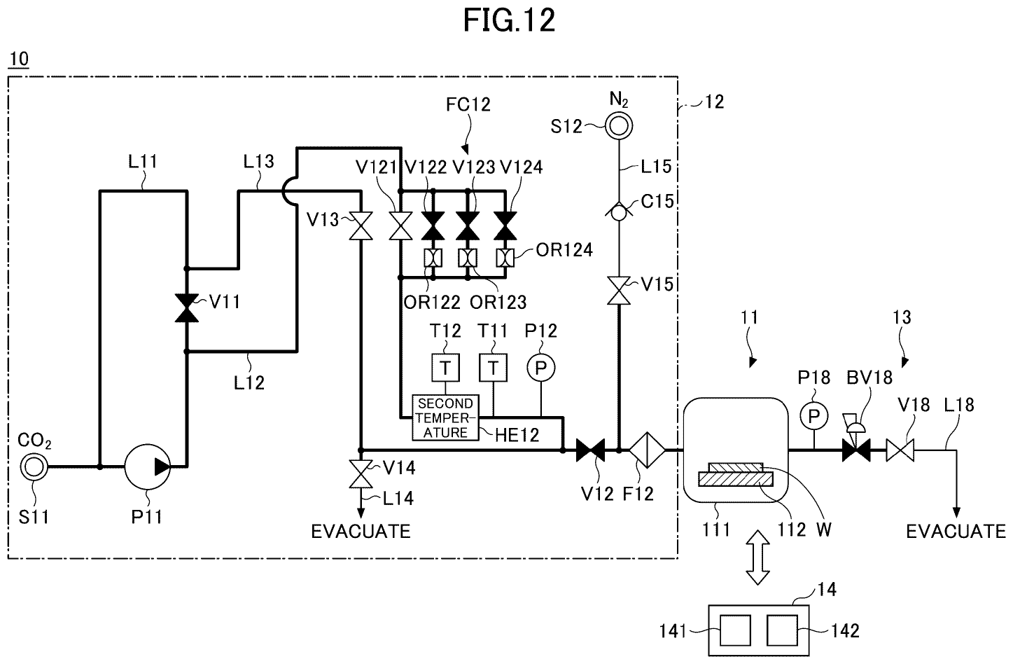

In the fourth pressure increasing step, as illustrated in FIG. 12, the set temperature of the heating mechanism HE12 is changed from the first temperature to the second temperature. With this, the processing fluid of the processing fluid supply source S11 is adjusted to the second temperature by passing through the heating mechanism HE12. Therefore, the processing fluid at the third flow rate and at the second temperature is supplied into the processing chamber 111. As described, while the processing fluid is supplied into the processing chamber 111, the heating mechanism HE12 is controlled to increase the temperature of the processing fluid from the first temperature to the second temperature. In the case of the heating mechanism HE12 using optical heating, the thermal capacity is small, and thus, the temperature responsiveness is high. Therefore, the temperature of the processing fluid can be raised from the first temperature to the second temperature in a short time. In the fourth pressure increasing step, the on-off valve V18 is closed, and thus the processing fluid does not flow out from the processing chamber 111. Therefore, the pressure in the processing chamber 111 gradually increases.

During the fourth pressure increasing step, the pressure in the processing chamber 111 is detected by the pressure sensor P18, and the fourth pressure increasing step is continued until the pressure in the processing chamber 111 reaches a fourth pressure Y4 (see FIG. 4). When the pressure in the processing chamber 111 reaches the fourth pressure Y4, the fourth pressure increasing step is terminated and the process transitions to the flowing step.

As described above, in the pressure increasing step, the speed of pressure increase is increased in the order of the first pressure increasing step, the second pressure increasing step, and the third pressure increasing step. In this case, the processing fluid is prevented from being supplied to the substrate W at a high speed in the initial stage, and pattern collapse can be suppressed.

During this series of operations, the controller 14 receives the outputs from the pressure sensor P12, the first temperature sensor T11, and the second temperature sensor T12, calculates the hypothetical temperature by Equation (1), and controls the output of the heating mechanism HE12 based on the calculated hypothetical temperature.

In the pressure increasing step ST12, the processing fluid in the gas state flows through the pipe L12p during a period from immediately after the start to partway through the pressure increase. Thus, the controller 14 sets the second weight coefficient β to a value greater than the first weight coefficient x. As illustrated in FIG. 5, the controller 14 sets the first weight coefficient α in the range of 0<α≤0.5, and sets the second weight coefficient β in the range of 0.5≤β<1, for example. When the processing fluid in the gas state flows through the pipe L12p, the response speed of the first temperature sensor T11 is low. Therefore, by reducing the contribution of the first temperature sensor T11 and increasing the contribution of the second temperature sensor T12, the temperature controllability is improved.

In the pressure increasing step ST12, the processing fluid in the supercritical state flows through the pipe L12p during a period from partway through the pressure increase to the end of the pressure increase. Thus, the controller 14 sets the first weight coefficient α to a value greater than the second weight coefficient β. As illustrated in FIG. 5, the controller 14 sets the first weight coefficient α in the range of 0.9≤α<1, and sets the second weight coefficient β in the range of 0<β≤0.1, for example. When the processing fluid in the supercritical state flows through the pipe L12p, the response speed of the first temperature sensor T11 is high. Therefore, by increasing the contribution of the first temperature sensor T11 and reducing the contribution of the second temperature sensor T12, the temperature controllability is improved.

The controller 14 may determine which state, among the multiple states, is the current state in the pipe L12p, based on, for example, the pressure of the processing fluid detected by the pressure sensor P12.

### <Flowing Step ST13>

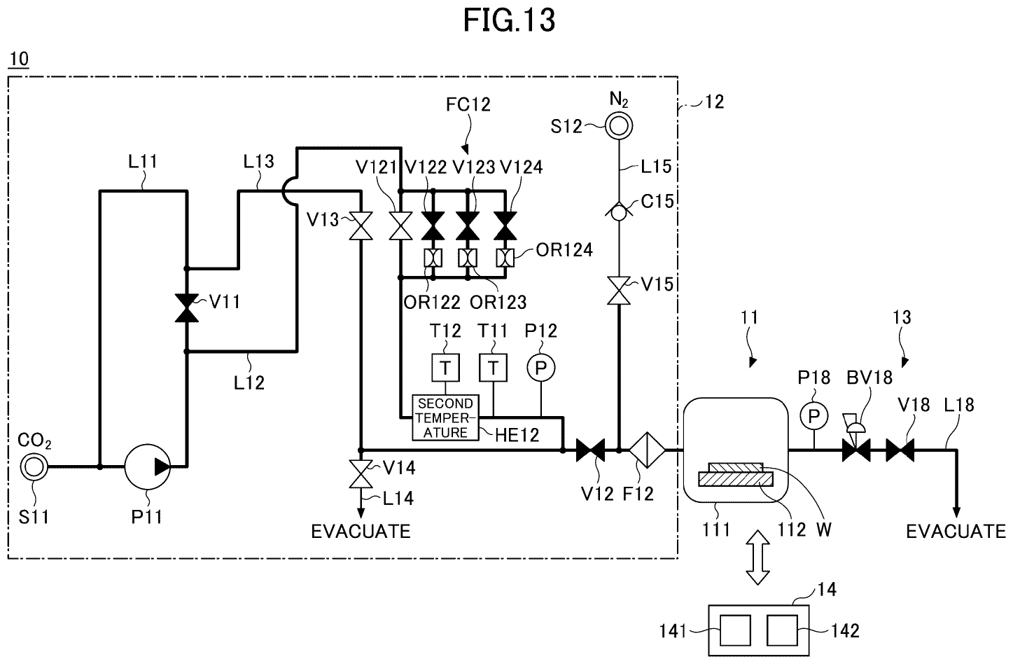

The flowing step ST13 is performed after the pressure increasing step ST12. In the flowing step ST13, the processing fluid at the third flow rate and at the second temperature is supplied from the processing fluid supply source S11 into the processing chamber 111, and the replacement of the IPA with the processing fluid is performed in the recess of the pattern on the substrate W in the processing chamber 111. Specifically, as illustrated in FIG. 13, the on-off valve V18 switches from closed to open. With this, the processing fluid of the processing fluid supply source S11 is supplied into the processing chamber 111 through the circulation flow path L11 and the first supply flow path L12, and is evacuated from the processing chamber 111 through the evacuation flow path L18. Therefore, the pressure in the processing chamber 111 is maintained at the fourth pressure Y4 (see FIG. 4). By performing the flowing step ST13, the replacement of the IPA with the processing fluid in the recess of the pattern of the substrate W is promoted.

When the replacement of the IPA with the processing fluid in the recess of the pattern is completed, the flowing step ST13 is terminated and the process transitions to the pressure reducing step ST14.

During this series of operations, the controller 14 receives the outputs from the pressure sensor P12, the first temperature sensor T11, and the second temperature sensor T12, calculates the hypothetical temperature by Equation (1), and controls the output of the heating mechanism HE12 based on the calculated hypothetical temperature.

In the flowing step ST13, the processing fluid in the supercritical state flows through the pipe L12p. Thus, the controller 14 sets the first weight coefficient α to a value greater than the second weight coefficient β. As illustrated in FIG. 5, the controller 14 sets the first weight coefficient α in the range of 0.9≤α<1, and sets the second weight coefficient β in the range of 0<β≤0.1, for example. When the processing fluid in the supercritical state flows through the pipe L12p, the response speed of the first temperature sensor T11 is high. Therefore, by increasing the contribution of the first temperature sensor T11 and reducing the contribution of the second temperature sensor T12, the temperature controllability is improved.

The controller 14 may determine which state, among the multiple states, is the current state in the pipe L12p, based on the pressure of the processing fluid detected by the pressure sensor P12, for example.

### <Pressure Reducing Step ST14>

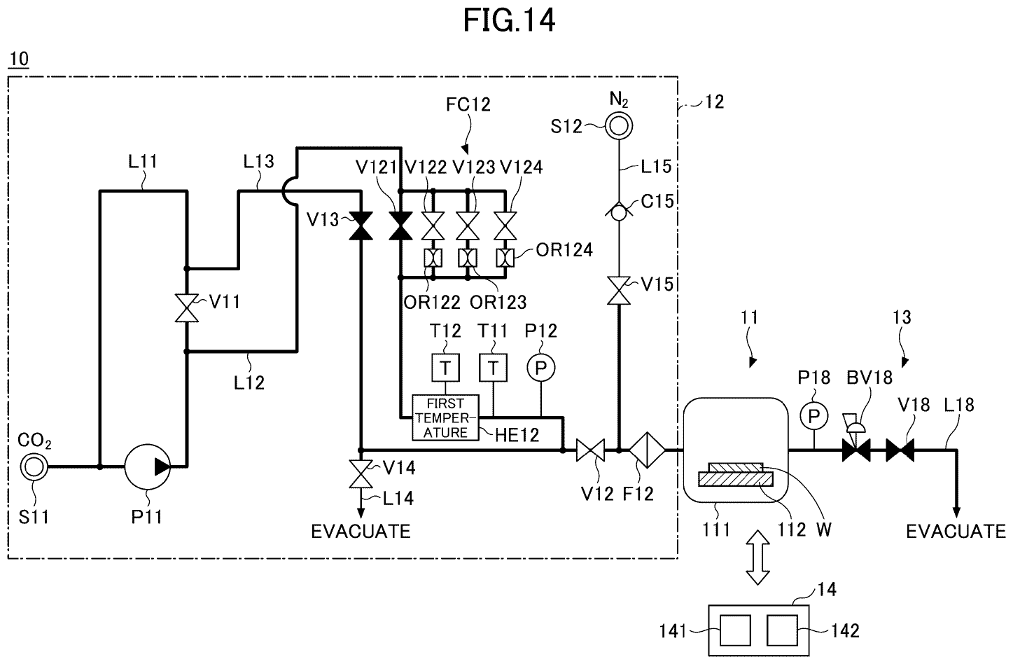

The pressure reducing step ST14 is performed after the flowing step ST13. In the pressure reducing step ST14, the processing fluid is evacuated from the processing chamber 111. Specifically, as illustrated in FIG. 14, the on-off valve V12 switches from open to closed. With this, the processing fluid remaining in the processing chamber 111 is evacuated from the evacuation flow path L18. When the pressure in the processing chamber 111 becomes lower than the critical pressure of the processing fluid due to the pressure reducing step ST14, the processing fluid in the supercritical state is vaporized and separated from the recess of the pattern. Then, the drying process for one substrate W is completed.

In the pressure reducing step ST14, as illustrated in FIG. 14, the set temperature of the heating mechanism HE12 is changed from the second temperature to the first temperature, the on-off valves V11, V122, V123, and V124 switch from open to closed, and the on-off valves V121 and V13 switch from closed to open. With this, the processing fluid of the processing fluid supply source S11 circulates through the circulation flow path L11, the first supply flow path L12, and the return flow path L13, and is lowered in temperature from the second temperature to the first temperature. In this case, the evacuation of the processing fluid from the processing chamber 111 and the preparation of the processing fluid to be used for the processing on the next substrate W can be performed in parallel. Therefore, the processing time in the continuous processing can be shortened.

In the pressure reducing step ST14, the on-off valves V122, V123, and V124 may switch from open to closed, the on-off valve V11 may be maintained to be open, and the on-off valves V121 and V13 may be maintained to be closed. In this case, the processing fluid of the processing fluid supply source S11 circulates through the circulation flow path L11.

During this series of operations, the controller 14 receives the outputs from the pressure sensor P12, the first temperature sensor T11, and the second temperature sensor T12, calculates the hypothetical temperature by Equation (1), and controls the output of the heating mechanism HE12 based on the calculated hypothetical temperature.

In the pressure reducing step ST14, the processing fluid does not flow through the pipe L12p, or the processing fluid in the gas state flows through the pipe L12p. Thus, the controller 14 sets the second weight coefficient β to a value greater than the first weight coefficient x. In the pressure reducing step ST14, the temperature change due to the volume expansion of the processing fluid during the pressure reduction is great, and thus the temperature detected by the first temperature sensor T11 is likely to fluctuate. Therefore, the controller 14 sets the second weight coefficient β to a value greater than the second weight coefficient β in the standby step ST11. As illustrated in FIG. 5, the controller 14 sets the first weight coefficient α in the range of 0<α≤0.1, and sets the second weight coefficient β in the range of 0.9≤β<1, for example. When the processing fluid does not flow through the pipe L12p or when the pipe L12p is filled with the processing fluid in the gas state, the response speed of the first temperature sensor T11 is low. Therefore, by reducing the contribution of the first temperature sensor T11 and increasing the contribution of the second temperature sensor T12, the temperature controllability is improved. The controller 14 determines which state, among the multiple states, is the current state in the pipe L12p, based on the pressure of the processing fluid detected by the pressure sensor P12, for example.

After the pressure reducing step ST14, the process transitions to the standby step ST11. The processed substrate W is carried out from the processing chamber 111 after the process transitions to the standby step ST11, for example. Specifically, after the pressure reducing step ST14, the supply of the inert gas into the processing chamber 111 through the second supply flow path L15 is started. Then, the substrate W is carried out from the processing chamber 111 in a state where the inert gas is supplied into the processing chamber 111. Even after the substrate W is carried out from the processing chamber 111, the supply of the inert gas into the processing chamber 111 is continued. As described, when the substrate W is carried out from the processing chamber 111 in a state where the inert gas is supplied into the processing chamber 111, the inside of the processing chamber 111 is at positive pressure, and thus, when the inside of the processing chamber 111 is opened, a gas flow is formed from the inside of the processing chamber 111 toward the outside. Therefore, the residue in the processing chamber 111 can be evacuated to the outside of the processing chamber 111 and removed. However, when the substrate W is carried out from the processing chamber 111, the supply of the inert gas into the processing chamber 111 may be stopped.

In the substrate processing method according to the embodiment described above, the case where the heating mechanism HE12 is controlled to increase the temperature of the processing fluid from the first temperature to the second temperature in the pressure increasing step ST12 has been described, but the present disclosure is not limited thereto. For example, in the flowing step ST13, the heating mechanism HE12 may be controlled to increase the temperature of the processing fluid from the first temperature to the second temperature. For example, in the standby step ST11, the pressure increasing step ST12, the flowing step ST13, and the pressure reducing step ST14, the set temperature of the heating mechanism HE12 may be fixed to a constant value.

### [Control of Temperature]

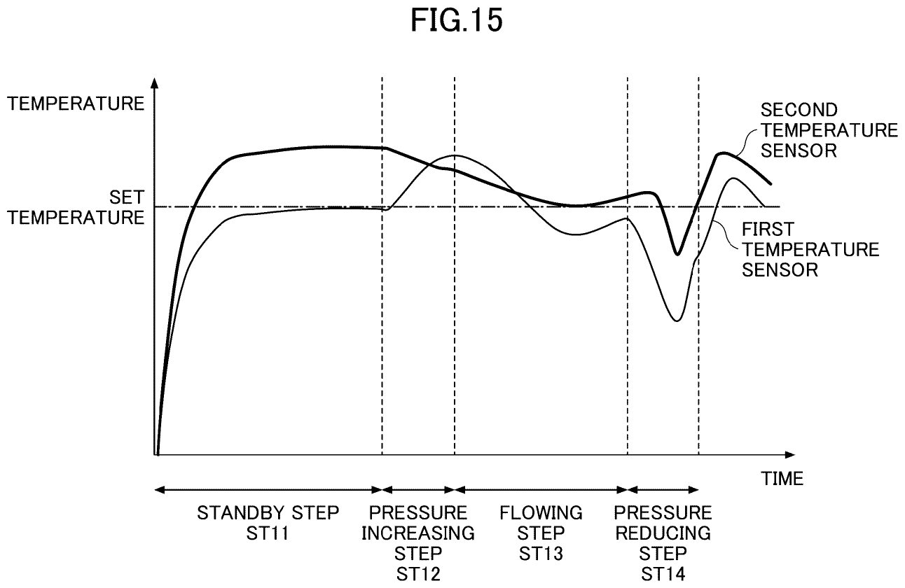

The control of the temperature in the case of controlling the output of the heating mechanism HE12 based on only the temperature detected by the first temperature sensor T11 will be described with reference to FIG. 15. FIG. 15 is a graph indicating a temperature change in the case where the heating mechanism HE12 is controlled based on only the temperature detected by the first temperature sensor T11. In FIG. 15, the thin solid line indicates the temperature detected by the first temperature sensor T11, the thick solid line indicates the temperature detected by the second temperature sensor T12, and the dash-dotted line indicates the set temperature.

When the output of the heating mechanism HE12 is controlled based on only the temperature detected by the first temperature sensor T11, the temperature detected by the second temperature sensor T12 is higher than the set temperature in the standby step ST11. That is, the temperature in the pipe L12p becomes higher than the set temperature. Immediately after the transition from the standby step ST11 to the pressure increasing step ST12, the processing fluid flows through the pipe L12p heated to a temperature higher than the set temperature, and thus the processing fluid is heated to a temperature higher than the set temperature. Therefore, the temperature detected by the first temperature sensor T11 becomes higher than the set temperature immediately after the transition from the standby step ST11 to the pressure increasing step ST12, and changes to approach the set temperature as time elapses. That is, in the pressure increasing step ST12 and the flowing step ST13, the temperature of the processing fluid supplied into the processing chamber 111 is not stable. In the pressure reducing step ST14, the temperature in the pipe L12p is rapidly decreased due to the volume expansion in the pipe L12p, and the temperature detected by the first temperature sensor T11 is significantly lower than the set temperature. The output of the heating mechanism HE12 is controlled so that the temperature detected by the first temperature sensor T11 becomes the set temperature, but the temperature in the pipe L12p rapidly increases and overshoot tends to occur.

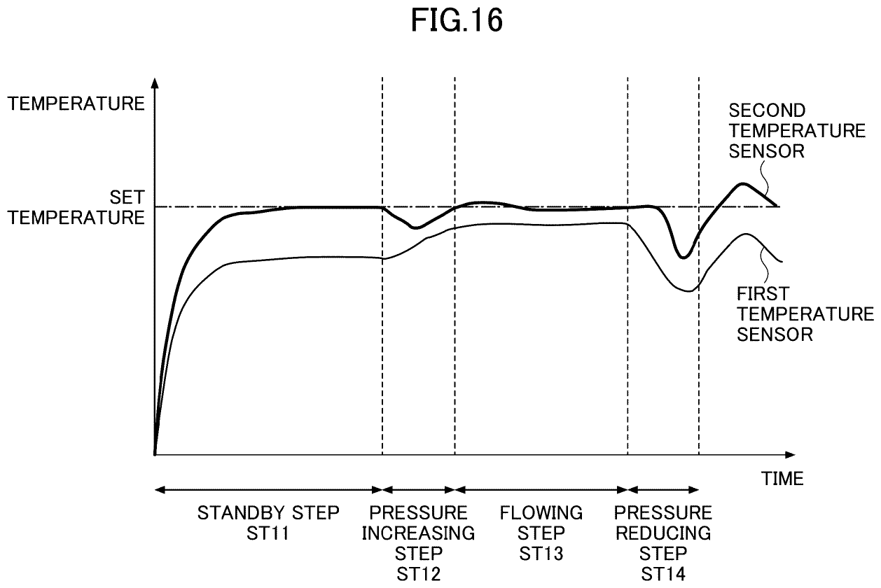

The control of the temperature in the case where the output of the heating mechanism HE12 is controlled based on only the temperature detected by the second temperature sensor T12 will be described with reference to FIG. 16. FIG. 16 is a graph indicating a temperature change in the case where the heating mechanism HE12 is controlled based on only the temperature detected by the second temperature sensor T12. In FIG. 16, the thin solid line indicates the temperature detected by the first temperature sensor T11, the thick solid line indicates the temperature detected by the second temperature sensor T12, and the dash-dotted line indicates the set temperature.

In the case where the heating mechanism HE12 is controlled based on only the temperature detected by the second temperature sensor T12, the temperature detected by the first temperature sensor T11 is lower than the set temperature in the pressure increasing step ST12 and the flowing step ST13. The temperature of the processing fluid supplied into the processing chamber 111 is substantially equal to the temperature detected by the first temperature sensor T11. Therefore, in the pressure increasing step ST12 and the flowing step ST13, the processing fluid having a temperature lower than the set temperature is supplied into the processing chamber 111.

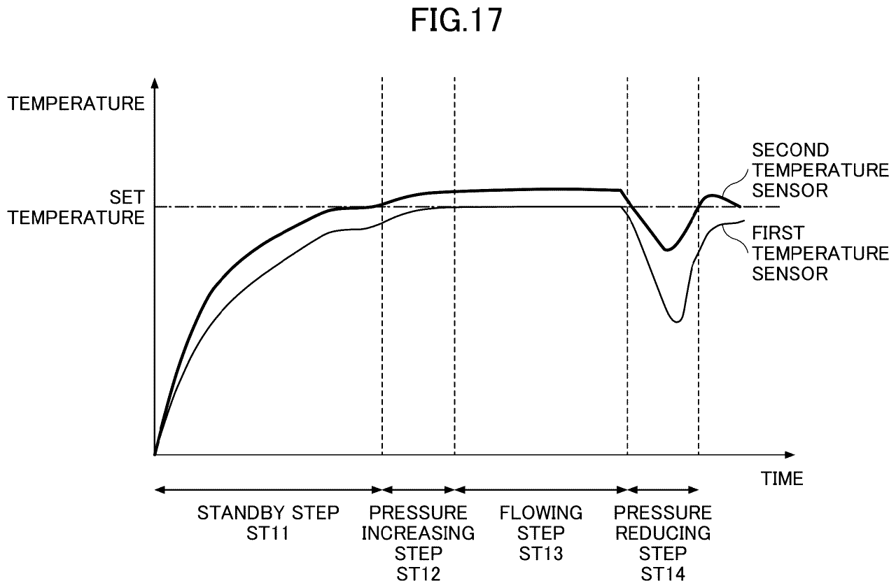

The control of the temperature in the case of controlling the output of the heating mechanism HE12 based on the hypothetical temperature calculated by Equation (1) will be described with reference to FIG. 17. FIG. 17 is a diagram indicating a temperature change in the case of controlling the heating mechanism HE12 based on the hypothetical temperature. In FIG. 17, the thin solid line indicates the temperature detected by the first temperature sensor T11, the thick solid line indicates the temperature detected by the second temperature sensor T12, and the dash-dotted line indicates the set temperature.

When the output of the heating mechanism HE12 is controlled based on the hypothetical temperature, the ratio of the contribution of the first temperature sensor T11 to the contribution of the second temperature sensor T12 can be changed in accordance with the pressure in the pipe L12p.

In the standby step ST11, the second weight coefficient β is set to a value greater than the first weight coefficient α. For example, the first weight coefficient α is set to 0.1, and the second weight coefficient β is set to 0.9. In this case, the contribution of the second temperature sensor T12 is higher than the contribution of the first temperature sensor T11. Therefore, in the standby step ST11, the temperature detected by the second temperature sensor T12 becomes substantially equal to the set temperature.

Immediately after the transition from the standby step ST11 to the pressure increasing step ST12, the processing fluid passes through the pipe L12p heated to a temperature substantially equal to the set temperature, and thus the temperature of the processing fluid becomes substantially equal to the set temperature. Thus, the temperature detected by the first temperature sensor T11 hardly changes immediately after the transition from the standby step ST11 to the pressure increasing step ST12. In the pressure increasing step ST12, the first weight coefficient α in the period in which the processing fluid in the gas state flows through the pipe L12p is set to a value greater than the first weight coefficient α in the standby step ST11. For example, the first weight coefficient α is set to 0.3, and the second weight coefficient β is set to 0.7. The first weight coefficient α is set to a value greater than the second weight coefficient β in the period in which the processing fluid in the supercritical state flows through the pipe L12p in the pressure increasing step ST12 and in the flowing step ST13. For example, the first weight coefficient α is set to 0.99, and the second weight coefficient β is set to 0.01. In this case, in the pressure increasing step ST12 and the flowing step ST13, the temperature detected by the first temperature sensor T11 is maintained to be substantially equal to the set temperature. Therefore, in the pressure increasing step ST12 and the flowing step ST13, the processing fluid whose temperature is substantially equal to the set temperature is supplied into the processing chamber 111. That is, the temperature of the processing fluid can be brought close to the set temperature regardless of the state of the processing fluid.

In the pressure reducing step ST14, the second weight coefficient β is set to a value greater than the first weight coefficient α. For example, the first weight coefficient α is set to 0.01, and the second weight coefficient β is set to 0.99. In this case, the contribution of the second temperature sensor T12 becomes higher than the contribution of the first temperature sensor T11. In the pressure reducing step ST14, the temperature in the pipe L12p rapidly decreases due to the volume expansion in the pipe L12p, and the temperature detected by the first temperature sensor T11 becomes a temperature significantly lower than the set temperature. At this time, the output of the heating mechanism HE12 is controlled so that the temperature detected by the second temperature sensor T12 mainly becomes the set temperature. The temperature detected by the second temperature sensor T12 is closer to the set temperature than the temperature detected by the first temperature sensor T11 is. Therefore, the temperature in the pipe L12p is prevented from rapidly increasing in comparison with the case where the output of the heating mechanism HE12 is controlled so that the temperature detected by the first temperature sensor T11 becomes the set temperature, thereby suppressing overshoot.

The embodiments disclosed herein are to be considered as illustrative in all respects and not restrictive. Various omissions, substitutions, and changes may be made to the above-described embodiments without departing from the scope and spirit of the appended claims.

In the above-described embodiment, the case where the output of the heating mechanism HE12 is controlled based on the pressure of the processing fluid detected by the pressure sensor P12, the temperature of the processing fluid detected by the first temperature sensor T11, and the temperatures of the pipe L12p detected by the second temperature sensor T12 has been described. However, the present disclosure is not limited thereto. For example, the pressure of the processing fluid detected by the pressure sensor P18 may be used instead of the pressure of the processing fluid detected by the pressure sensor P12. For example, the set temperature may be used instead of the temperature of the pipe L12p detected by the second temperature sensor T12.

In the above-described embodiment, the case where the heating mechanism HE12 is provided outside the pipe L12p and the processing fluid flowing through the pipe L12p is heated by radiating the light toward the pipe L12p from the outside of the pipe L12p has been described, but the present disclosure is not limited thereto.

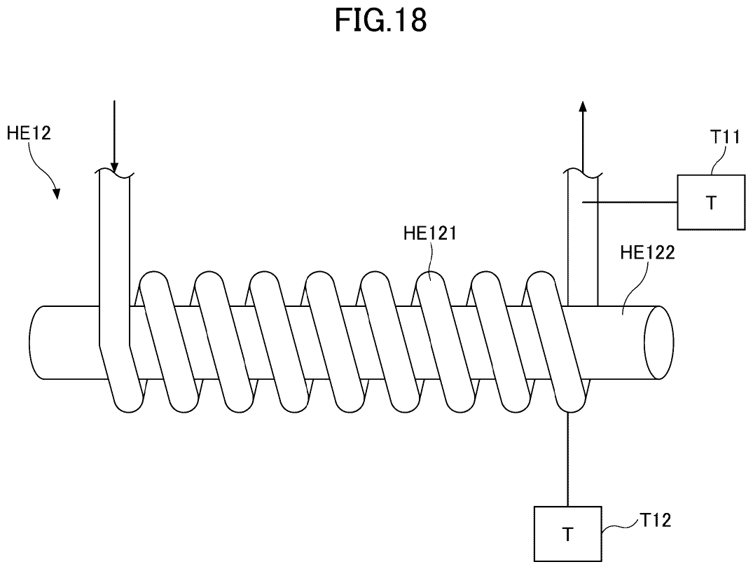

FIG. 18 is a diagram illustrating a heating mechanism HE12 according to a first modified example. As illustrated in FIG. 18, the heating mechanism HE12 includes a spiral pipe HE121 and a heater HE122. The spiral pipe HE121 is provided spirally around the heater HE122. The processing fluid flows through the spiral pipe HE121. The spiral pipe HE121 is formed of, for example, stainless steel. The heater HE122 is provided inside the spiral of the spiral pipe HE121. The heater HE122 has a rod shape. The heater HE122 radiates light from the inside of the spiral of the spiral pipe HE121 toward the spiral pipe HE121 to heat the spiral pipe HE121 and the processing fluid flowing through the spiral pipe HE121. In the example of FIG. 18, the temperature measurement element of the first temperature sensor T11 is inserted into the spiral pipe HE121 near the outlet of the spiral pipe HE121, and detects the temperature of the processing fluid flowing through the spiral pipe HE121. The temperature measurement element of the second temperature sensor T12 is provided in contact with the outer wall of the spiral pipe HE121, and detects the temperature of the spiral pipe HE121.

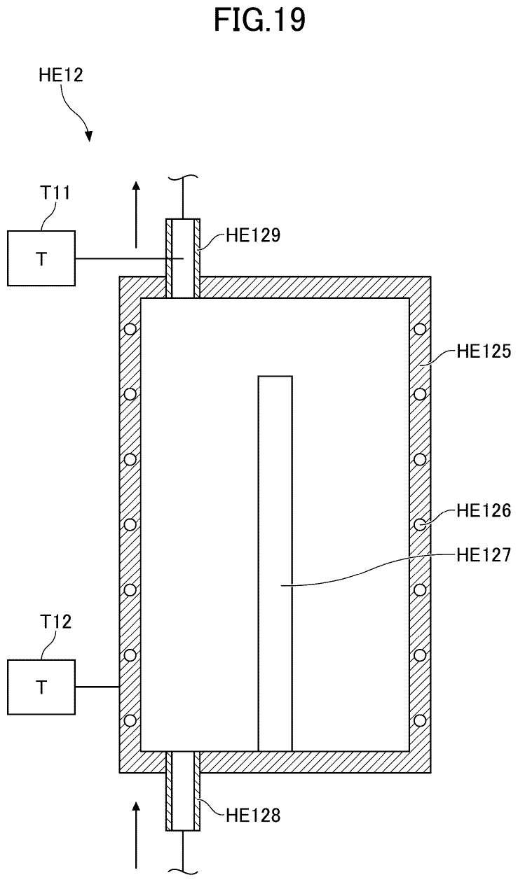

FIG. 19 is a diagram illustrating a heating mechanism HE12 according to a second modified example. As illustrated in FIG. 19, the heating mechanism HE12 includes a tank HE125, a heater HE126, and a heater HE127. The tank HE125 stores the processing fluid. The tank HE125 is made of, for example, stainless steel. The heater HE126 is embedded in the wall of the tank HE125. The heater HE127 is provided inside the tank HE125. The heater HE126 and the heater HE127 heat the tank HE125 and the processing fluid stored in the tank HE125. A first connection port HE128 and a second connection port HE129 are provided on the tank HE125. The processing fluid is supplied into the tank HE125 through the first connection port HE128, and the processing fluid is evacuated from the tank HE125 through the second connection port HE129. In the example of FIG. 19, the temperature measurement element of the first temperature sensor T11 is inserted into the second connection port HE129 and detects the temperature of the processing fluid flowing through the second connection port HE129. The temperature measurement element of the second temperature sensor T12 is provided in contact with the outer wall of the tank HE125, and detects the temperature of the tank HE125.

According to the present disclosure, the temperature of the processing fluid can be brought close to the set temperature regardless of the state of the processing fluid.

What is claimed is:

1. A substrate processing apparatus comprising:
a processing chamber configured to accommodate a substrate;
a supply flow path configured to supply a processing fluid into the processing chamber;
a heating mechanism configured to heat the processing fluid flowing through the supply flow path;
a first temperature sensor configured to detect a temperature of the processing fluid downstream of the heating mechanism;
a pressure sensor configured to detect a pressure of the processing fluid downstream of the heating mechanism; and
a controller;
wherein the controller controls an output of the heating mechanism based on the pressure of the processing fluid detected by the pressure sensor and the temperature of the processing fluid detected by the first temperature sensor.

2. The substrate processing apparatus as claimed in claim 1,
wherein the controlling of the output of the heating mechanism includes:
calculating a first calculation temperature by multiplying the temperature of the processing fluid detected by the first temperature sensor by a first weight coefficient; and
controlling the output of the heating mechanism based on the first calculation temperature, and
wherein the first weight coefficient is a value associated with the pressure of the processing fluid detected by the pressure sensor.

3. The substrate processing apparatus as claimed in claim 2, wherein the first weight coefficient that is set when the pressure of the processing fluid is a first pressure is less than the first weight coefficient that is set when the pressure of the processing fluid is a second pressure that is higher than the first pressure.

4. The substrate processing apparatus as claimed in claim 2, further comprising a second temperature sensor configured to detect a temperature of the supply flow path heated by the heating mechanism,
wherein the controlling of the output of the heating mechanism includes:
calculating a second calculation temperature by multiplying the temperature of the supply flow path detected by the second temperature sensor by a second weight coefficient; and
controlling the output of the heating mechanism based on the first calculation temperature and the second calculation temperature, and
wherein the second weight coefficient is a value associated with the pressure of the processing fluid detected by the pressure sensor.

5. The substrate processing apparatus as claimed in claim 4, wherein the second weight coefficient that is set when the pressure of the processing fluid is a first pressure is greater than the second weight coefficient that is set when the pressure of the processing fluid is a second pressure that is higher than the first pressure.

6. The substrate processing apparatus as claimed in claim 4, wherein the controller sets the first weight coefficient to a value greater than the second weight coefficient, in a case where the processing fluid flowing through the supply flow path is in a supercritical state.

7. The substrate processing apparatus as claimed in claim 4, wherein the controller sets the first weight coefficient to a value less than the second weight coefficient, in a case where the processing fluid flowing through the supply flow path is in a gas state.

8. The substrate processing apparatus as claimed in claim 4, wherein the controller sets the first weight coefficient to a value less than the second weight coefficient, in a case where the processing fluid does not flow through the supply flow path.

9. The substrate processing apparatus as claimed in claim 1, wherein the controller controls the output of the heating mechanism while causing the processing fluid to flow from the supply flow path into the processing chamber.

10. The substrate processing apparatus as claimed in claim 1, wherein the heating mechanism includes a lamp heater.

11. A fluid supply system comprising:
a supply flow path configured to supply a processing fluid into a processing chamber;
a heating mechanism configured to heat the processing fluid flowing through the supply flow path;
a first temperature sensor configured to detect a temperature of the processing fluid downstream of the heating mechanism;
a pressure sensor configured to detect a pressure of the processing fluid downstream of the heating mechanism; and
a controller;
wherein the controller controls an output of the heating mechanism based on the pressure of the processing fluid detected by the pressure sensor and the temperature of the processing fluid detected by the first temperature sensor.

12. A substrate processing method using a substrate processing apparatus including:
a processing chamber configured to accommodate a substrate;
a supply flow path configured to supply a processing fluid into the processing chamber;
a heating mechanism configured to heat the processing fluid flowing through the supply flow path;
a first temperature sensor configured to detect a temperature of the processing fluid downstream of the heating mechanism; and
a pressure sensor configured to detect a pressure of the processing fluid downstream of the heating mechanism, the substrate processing method comprising controlling an output of the heating mechanism based on the pressure of the processing fluid detected by the pressure sensor and the temperature of the processing fluid detected by the first temperature sensor.

13. The substrate processing method as claimed in claim 12,
wherein the controlling of the output of the heating mechanism includes:
calculating a first calculation temperature by multiplying the temperature of the processing fluid detected by the first temperature sensor by a first weight coefficient; and
controlling the output of the heating mechanism based on the first calculation temperature, and
wherein the first weight coefficient is a value associated with the pressure of the processing fluid detected by the pressure sensor.

14. The substrate processing method as claimed in claim 13, wherein the first weight coefficient that is set when the pressure of the processing fluid is a first pressure is less than the first weight coefficient that is set when the pressure of the processing fluid is a second pressure that is higher than the first pressure.

15. The substrate processing method as claimed in claim 13,
wherein the substrate processing apparatus further includes a second temperature sensor configured to detect a temperature of the supply flow path heated by the heating mechanism,
wherein the controlling of the output of the heating mechanism includes:
calculating a second calculation temperature by multiplying the temperature of the supply flow path detected by the second temperature sensor by a second weight coefficient; and
controlling the output of the heating mechanism based on the first calculation temperature and the second calculation temperature, and
wherein the second weight coefficient is a value associated with the pressure of the processing fluid detected by the pressure sensor.

16. The substrate processing method as claimed in claim 15, wherein the second weight coefficient that is set when the pressure of the processing fluid is a first pressure is greater than the second weight coefficient that is set when the pressure of the processing fluid is a second pressure that is higher than the first pressure.

17. The substrate processing method as claimed in claim 15, wherein the first weight coefficient is set to a value greater than the second weight coefficient, in a case where the processing fluid flowing through the supply flow path is in a supercritical state.

18. The substrate processing method as claimed in claim 15, wherein the first weight coefficient is set to a value less than the second weight coefficient, in a case where the processing fluid flowing through the supply flow path is in a gas state.

19. The substrate processing method as claimed in claim 15, wherein the first weight coefficient is set to a value less than the second weight coefficient, in a case where the processing fluid does not flow through the supply flow path.

20. The substrate processing method as claimed in claim 12, wherein the controlling of the output of the heating mechanism includes controlling the output of the heating mechanism while causing the processing fluid to flow from the supply flow path into the processing chamber.
